(19) United States
(12) Patent Application Publication
(10) Pub. No.: US 2021/0203176 A1
(43) Pub. Date: Jul. 1, 2021

(54) POWER CONTROL SYSTEM FOR ELECTRICAL APPARATUS

(71) Applicant: HEWLETT-PACKARD DEVELOPMENT COMPANY, L.P., Houston, TX (US)

(72) Inventors: Arthur H. BARNES, Houston, TX (US); David E. SMITH, Houston, TX (US); William WINTERS, Houston, TX (US)

(73) Assignee: HEWLETT-PACKARD DEVELOPMENT COMPANY, L.P., Houston, TX (US)

(21) Appl. No.: 16/076,300

(22) PCT Filed: Apr. 28, 2017
(86) PCT No.: PCT/US2017/030226

§ 371 Date: Aug. 7, 2018

(51) Int. Cl. H02J 7/00; G01R 19/165; H02J 7/04; B29C 64/20; B33Y 30/00

(52) U.S. Cl. CPC H02J 7/0068; G01R 19/16542; B33Y 30/00; B29C 64/20; H02J 7/04

(57) ABSTRACT

A power control system enables an electrical apparatus to intermittently operate at power levels which exceed an available facility power. The power control system draws a sufficiently high current from a power source (e.g., mains supply) to supply power to components of the apparatus that generate a continuous below-threshold load, while at the same time, supplying a charge current for a battery module. The power control system can operate to use the battery module to supply power to components of the apparatus that draw excess power when the electrical apparatus operates at an above-threshold power level.

### BACKGROUND

Many electrical apparatus, such as those used for local manufacturing and printing, have intermittent power draws which often exceed those of the accompanying facility. Some facilities may have to reconfigure their mains supply to enable use of high-energy apparatuses.

### BRIEF DESCRIPTION OF THE DRAWINGS

The disclosure herein is illustrated by way of example, and not by way of limitation, in the figures of the accompanying drawings in which like reference numerals refer to similar elements, and in which:

FIG. 1 illustrates an example power control system for an electrical apparatus.

FIG. 2 illustrate another example power control system for use with an electrical apparatus;

FIG. 3 illustrates an example method for controlling power to an electrical apparatus.

Throughout the drawings, identical reference numbers designate similar, but not necessarily identical elements. The figures are not necessarily to scale, and the size of some parts may be exaggerated to more clearly illustrate the example shown. Moreover, the drawings provide examples and/or implementations with respect to the description. However, the description is not limited to the examples and/or implementations provided in the drawings.

### DETAILED DESCRIPTION

A power control system enables an electrical apparatus to intermittently operate at power levels which exceed an available facility power. The power control system draws a sufficiently high current from a power source (e.g., mains) to supply power to components of the apparatus that generate a continuous below-threshold load, while at the same time, supplying a charge current for a rechargeable battery module. The battery module can be charged to supply power to components of the apparatus that draw excess power when the electrical apparatus operates at an above-threshold power level.

In contrast to some conventional approaches, examples provide for a power control system that utilizes a battery module to supply power to components that cause the above-threshold load, independent of the power supply from the mains. Additionally, the power control system is able to modulate the charge current supplied to the battery module in order to accommodate fluctuations of the below-threshold load. In this way, a power control system such as described by various examples can enable use of a rechargeable battery module to supply power to a load of an electrical apparatus, where the load would otherwise exceed thresholds set by regulations (e.g., such as regulations as to flicker, harmonics, conductive emissions, etc.), facility operations, or other external constraints.

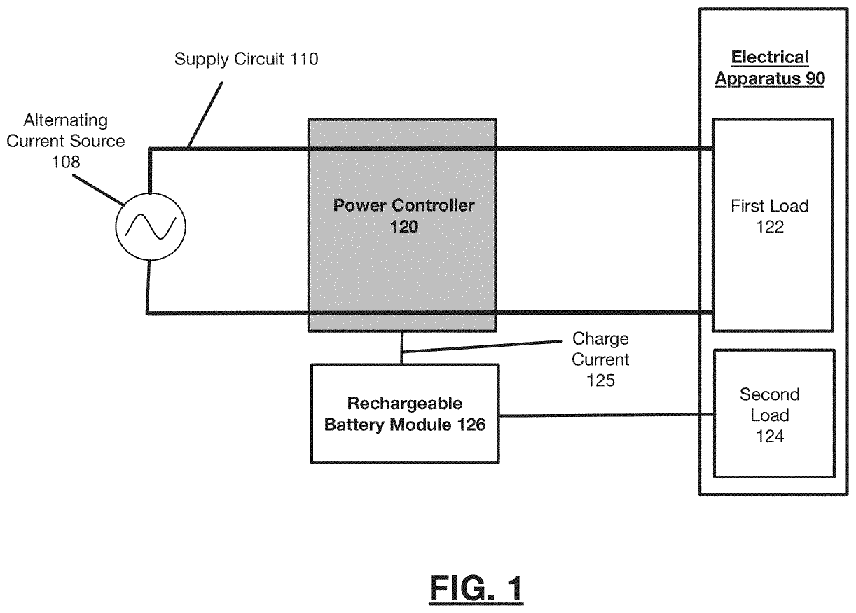

FIG. 1 illustrates an example power control system for an electrical apparatus. According to examples, the power control system 100 includes a supply circuit 110 and a power controller 120. The supply circuit 110 draws current from an alternating current source 108 in order to power a first set of electrical components (represented by first load 122) of an electrical apparatus 90. In some examples, the supply circuit 110 draws current from alternating current source 108 at a level that is below a predetermined threshold, and uses a proportion of the drawn current to continuously power the first load 122. In some examples the first load 122 may be well behaved such that the load meets regulatory thresholds (including regulatory thresholds for flicker, harmonics, conducted emissions, etc.). The power controller 120 supplies a charge current 125 to a rechargeable battery module 126 using a remainder of the proportion of the drawn current that powers the first load 122.

As described with other examples, the power controller 120 controls the amount of charge current 125 which the rechargeable battery module 126 receives, based on the amount of the source current the first load utilizes at a given time. In some examples, the power controller 120 modulates the charge current 125 such that the total amount of current which is drawn from the current source 108 remains constant (e.g., within range of 10%), even with fluctuations of the first load 122.

Additionally, the power controller 120 controls the battery module 126 in supplying power to a second set of high-energy consumption components (or components that violate regulatory requirements that are part of the electrical apparatus 90 (represented by the above-threshold load 124). The battery module 126 may be used to power the above-threshold load 124 during intervals when the corresponding high-energy consumption components of the electrical apparatus 90 are in use. In some variations, the above-threshold load 124 may be powered exclusively by the battery module 126, such that no affects of the above-threshold load 124 are felt on a facility where the electrical apparatus 90 is operated.

The input source 108 can correspond to an electrical outlet that operates at voltage, current and power levels that are typically set by standards that accompany an electrical grid at the location of the electrical apparatus 90. A predetermined threshold may be determined or otherwise set for the supply circuit 110 to be below the threshold limits of the electrical outlet. A proportion of the total amount of current drawn may be supplied to the first load 122, and the remainder may be supplied to the power controller 120 as the recharge current 125.

Among other benefits, the power supplied to the electrical apparatus 90 by the battery module 126 may be independent of the drawn current from the alternating current source 108. The power controller 120 includes circuit elements to power components that intermittently generate large electrical loads which exceed a threshold capacity of the alternating current source 108. According to examples, the electrical apparatus 90 may correspond to any assembly, machine or device which has intermittent power draws that exceed a threshold capacity of the alternating input source 108. By way of example, the electrical apparatus 90 may correspond to an additive manufacturing device (e.g., “3-D printer”), which processes service jobs to create three-dimensional structures from additive material (e.g., polyurethane composites, metals, etc.). In processing a service job, the overall power intake of the electrical apparatus 90 may multiply, in order to, for example, produce enough heat to melt additive material, and move a print head in 3-dimensional space. While numerous examples are described below in context of an additive or 3-D printer, other types of electrical apparatus may be utilized with examples as described.

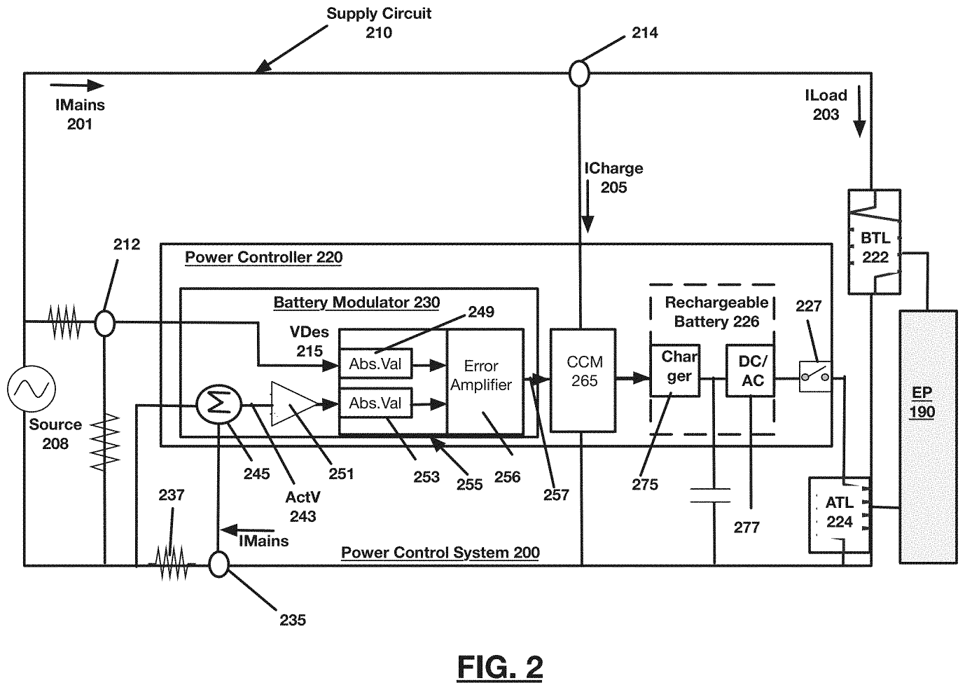

FIG. 2 illustrates an example power control system, for use with an electrical apparatus such as described with an example of FIG. 1. In some examples, a power control system 200 is provided as an integrated component or module of an electrical apparatus, such as an additive printer or manufacturing device, as described with an example of FIG. 1. In variations, the power control system 200 may be provided as an external connected component or accessory of the electrical apparatus.

The power control system 200 receives electrical power from an alternating current input source 208, and separately supplies power to each of a set of low power (or below threshold level) components (represented by below-threshold load 222) of the electrical apparatus 190, and a set of high power (or above threshold level) components (represented by above-threshold load 224). As described with other examples, the set of high power components may generate an intermittent and above-threshold load on the power control system 200. For example, the set of high electrical components may fluctuate, spike and/or sustain an above-threshold power level draw over a portion of the time period during which the electrical apparatus 190 operates. Depending on implementation, the above-threshold power draw may be sustained for durations that last seconds or minutes (but which may repeat) or hours.

In an example of FIG. 2, the power control system 200 includes a supply circuit 210 and a power controller 220, which combine to ensure the electrical apparatus 190 receives sufficient electrical power from the alternating current source 208 (e.g., standard outlet for a grid in a given geographic region) during periods in which the electrical apparatus operates at levels that significantly exceed the thresholds which are set for the alternating current source 208 (e.g., amperage on standard outlet for given geographic region). By way of example, the power control system 200 may implemented for an additive (or 3-D) printer, having an ability to draw power which would exceed those of a facility that uses standard grid outlets. As a specific example, the additive printer may have a maximum power draw of 3300 W, and such a power draw may cause flickering, circuit overload, outage or other events in many geographic locations, such as in Europe, where outlets are standardized at 230V/16 A. Among other benefits, the power control system 200 enables the electrical apparatus to receive sufficient power without requiring an operator of the electrical apparatus (or its facility) to make expensive alterations to the alternating current source 208 or its facility to enable the electrical apparatus to draw sufficient power.

Accordingly, with respect to an example of FIG. 2, the voltage divider 212 may be provided by a standard electrical outlet, which operates under predetermined threshold levels that are set by local regulations or third-party standards. The power control system 200 may draw current from the source 208 to supply power to components that provide a below-threshold load 222 on the electrical apparatus. In some examples, the below-threshold load 222 may be present for the entire duration of the electrical apparatus' operating cycle. The power control system 200 may also draw current from the source 208 to supply power to battery module 226.

In some implementations, the electrical apparatus 190 may include intermittent periods of high-energy usage which exceeds the predetermined threshold for the electrical apparatus 190 or its facility. Depending on implementation, the intermittent periods of operation may range in seconds, minutes or hours, during which an above-threshold load 224 is present. When the above-threshold load 224 is present, the power controller 220 can trigger the battery module 126 to power to the components that generate the above-threshold load 224.

In some examples, the below-threshold load 222 may fluctuate between a range of values, with an upper limit of the range being less than the predetermined threshold. By way of example, the below-threshold load 222 may be generated from components that operate the electrical apparatus' user interface, processor, communication components, motors, and other hardware components. Such components may be operable at different levels of power below the threshold. For example, the below-threshold load 222 may be implemented by a set of internal components of the electrical apparatus that operate in each of a low power mode when the electrical apparatus is on stand-bye to receive a service job, as well as in a high-power state when, for example, a user is interacting with the user interface of the electrical apparatus. For such components, the low and high power states may remain at or below the predetermined threshold.

Likewise, the above-threshold load 224 can be generated by components of the electrical apparatus in response to, for example, a specific type of use. For example, when implemented as an additive printer, the above-threshold load 224 may be generated in-part from heating and robotic elements that may collectively draw power at levels that greatly exceed the predetermined threshold level.

According to an example of FIG. 2, the supply circuit 210 includes a voltage divider (represented by voltage divider node 212), and current divider (represented by current divider node 214. The voltage divider 212 sets as output a desired voltage level 215, which provides a predetermined threshold from which modulation of the charge current 205 can be made. The desired voltage level 215 may be selected to exceed the below-threshold load 222 of the electrical apparatus 190, but remain at a level that is within what the facility or grid can handle without unwanted consequences (e.g., flickering, circuit-break, etc.).

The current divider 214 distributes an input current 201 as load current 203 and charge current 205. Depending on usage and design of the electrical apparatus 190, the load current 203 can fluctuate over a range of values, based on, for example, a usage level of designated set of components which generate the below-threshold load 222. The fluctuation of the below-threshold load 222, the charge current 205 may also fluctuate. For example, when the below-threshold load 222 increases, the level of the charge current 205 may drop, and vice-versa.

According to examples, the electrical apparatus 190 can operate in multiple power modes, including in a low-power mode in which the below threshold load 222 is present, and a high-power mode in which both the below- and above-threshold loads 222, 224 are present. By way of example, on a 3D printer, the low-power mode may correspond to a standby mode, with components like processors, display components, network communication resources and other hardware components being enabled and or in use. The high-power mode, on the other hand, may include heat lamps, robotic elements and other resources used to melt and position material, as typical in many 3D printers.

With further reference to FIG. 2, the power controller 220 receives charge current 205 for the battery module 226. The power controller 220 includes a battery input modulator 230 that modulates a direct current input 257 for the battery module 226, based on the amount of current the below-threshold load 222 draws. The more current drawn by the below-threshold load 222, the less current drawn for charging the battery module 226.

Additionally, in some examples, the power controller 220 can operate to supply charge current 205 to the battery module 226 independent of the presence of the above-threshold load 224. Thus, the power controller 220 may operate to supply power to the below-threshold load 222 throughout the operational cycle of the electrical apparatus 190. As described, during intervals of the operational cycle when the above-threshold load 224 is present, the power controller 220 may trigger switching (represented by switch 227) of the battery module 226 to supply power for the above-threshold load 224.

In an example of FIG. 2, the battery modulator 230 includes current to voltage feedback element 245, signal comparator 255, and charge current modulator 265, and charger 275, which may include an alternating current to direct current (AC/DC) converter 275. The feedback node 235 receives the sum of load current 203 and the charge current 205. The current sum at the feedback node 235 may be set by the representative resistor 237 so that a corresponding actual voltage input 243 is determined at the output of current to voltage feedback element 245.

The signal comparator 255 can compare a modified form of the actual voltage input 243 with the desired voltage level 215. Depending on implementation, the actual voltage input 243 may be subjected to amplification (e.g., shown by current amplifier 251) and demodulation (e.g., shown by the absolute value circuit element 253). The battery modulator 230 also receives the desired voltage signal 215 as a reference signal. In one implementation, the desired voltage signal 215 may also be subjected to demodulation (e.g., shown by the absolute value circuit element 249).

In error amplifier 256, the modified (e.g., demodulated) desired voltage level 215 may be compared against the demodulated (and amplified) voltage input 243 in order to generate a modulation input 257 for the charge current modulator 265. In some examples, the modulation input 257 can reflect the near-instantaneous level of the current on the below-threshold load 222. The charge current modulator 265 can be calibrated or otherwise configured to map the modulation input 257 to switch elements, variable resistors or other current draw elements, so that the charge current 205 modulates in inverse relationship with the load current 203. According to some examples, the current input 201 remains relatively constant, eliminating fluctuation on the overall load experienced by the facility or grid. Moreover, the current input 201 can be maximized so that the battery module 226 is supplied a maximum level of charge current throughout the operational cycle of the electrical apparatus.

With reference to an example of FIG. 2, the power control system 200 may be responsive to the presence of the above-threshold load 224, to trigger a switch 227 for an output 229 of the battery module 226. When switched, the battery module 226 supplies the power for the above-threshold load 224, independent of the first load being powered by the 201 (e.g., AC mains). A DC/AC component 277 may generate the current output 229 to be alternating when supplied to the above-threshold load 224. The alternating current output 229 of the battery module 226 may power the high-energy components of the electrical apparatus 190 which constitute the above-threshold load 224. In this way, examples provide that the output 229 of the battery module 226 supplies power for the above-threshold load 224 without use of the source current 201, and without impact to the facility, which otherwise would not be able to handle the above-threshold load 224.

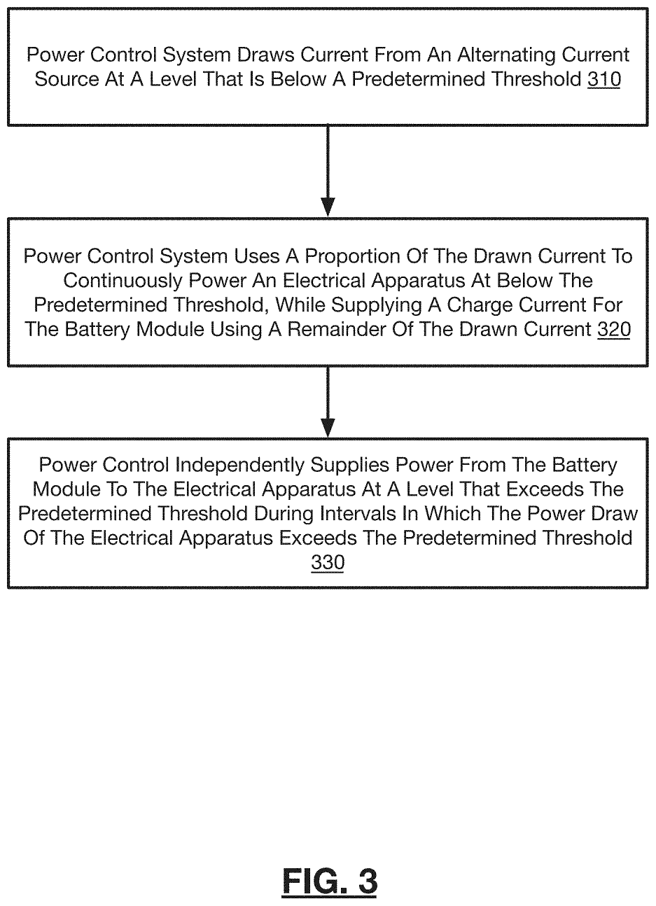

FIG. 3 illustrates an example method for controlling power to an electrical apparatus. In describing an example of FIG. 3, reference may be made to elements of FIG. 1, or FIG. 2, in order to illustrate suitable elements for implementing operations and functionality, as described. Depending on implementation, an example method as described may be performed by a power control system, which may be implemented as either an integral part of the electrical apparatus, or as an accessory (e.g., wall unit, converter for electrical cord, etc.) to the electrical apparatus.

With reference to an example of FIG. 3, the power control system 100, 200 draws current from an alternating current source 208 at a level that is below a predetermined threshold (310). The predetermined threshold may be determined by a variety of factors, such as facility capabilities (e.g., where the electrical apparatus is to operate), or settings which reflect a desired threshold. In some examples, the alternating current source 208 can correspond to, for example, an electrical outlet that is standardized for an electrical grid of a given geographic region.

The power control system 100, 200 may use a proportion of the drawn current to continuously power an electrical apparatus at below the predetermined threshold, while supplying a charge current for the battery module 126, 226 using a remainder of the drawn current (320). In some examples, the power control system 100, 200 continuously draws current to supply a designated load of the electrical apparatus during its operational cycle. The charge current may be modulated responsively, to account for the power supplied for the designated load of the electrical apparatus.

Additionally, the power control system 100, 200 may independently supply power from the battery to the electrical apparatus at a level that exceeds the predetermined threshold during intervals in which a power draw of the electrical apparatus exceeds the predetermined threshold (330). This may be done intermittently to accommodate, for example, fluctuating above-threshold loads on high-usage devices (e.g., loads which are present for seconds or minutes at a time). Alternatively, for some types of apparatuses, the above-threshold loads may be present for given durations of time within the operational cycle of the electrical apparatus (e.g., several hours per day). In such cases, the battery module 126, 226 may be of sufficient capacity to enable extended durations where the high-energy components of the electrical apparatus can be powered from its stored charge.

Although specific examples have been illustrated and described herein, it will be appreciated by those of ordinary skill in the art that a variety of alternate and/or equivalent implementations may be substituted for the specific examples shown and described without departing from the scope of the disclosure. This application is intended to cover any adaptations or variations of the specific examples discussed herein.

What is claimed is:

1. A power control system comprising:
a supply circuit to:
draw current from an alternating current source at a level that is below a predetermined threshold;
use a proportion of the drawn current to continuously power an electrical apparatus at below the predetermined threshold; and
a power controller to supply a charge current to the rechargeable battery module using a remainder of the proportion of the drawn current that powers the electrical apparatus, and to supply power to the electrical apparatus from the rechargeable battery module independent of the drawn current from the alternating current source, the supplied power of the rechargeable battery module meeting a power requirement of the electrical apparatus that would otherwise exceed the predetermined threshold.

2. The power control system of claim 1, wherein the power controller modulates the charge current based on a power requirement of the electrical apparatus when the electrical apparatus operates at below the predetermined threshold.

3. The power control system of claim 1, wherein the power controller independently supplies power from the rechargeable battery module to the electrical apparatus at a level that exceeds the predetermined threshold while the supply circuit uses the proportion of the drawn current to continuously power the electrical apparatus at below the predetermined threshold.

4. The power control system of claim 1 wherein the power controller independently supplies power from the rechargeable battery module to the electrical apparatus at a level that exceeds the predetermined threshold while the supply circuit supplies the charge current for the battery using the remainder of the drawn current.

5. The power control system of claim 1, wherein the power controller modulates the drawn current in supplying the charge current, so that the drawn current remains within a constant range, while the proportion of the drawn current powers a varying load of the electrical apparatus.

6. An electrical apparatus comprising:
a supply circuit to:
draw current from an alternating current source at a level that is below a predetermined threshold;
use a proportion of the drawn current to continuously power an electrical apparatus at below the predetermined threshold; and
a power controller to supply a charge current to the rechargeable battery module using a remainder of the proportion of the drawn current that powers the electrical apparatus, and to supply power to the electrical apparatus from the rechargeable battery module independent of the drawn current from the alternating current source, the supplied power of the rechargeable battery module meeting a power requirement of the electrical apparatus that would otherwise exceed the predetermined threshold.

7. The electrical apparatus of claim 6, wherein the first load of the electrical apparatus is provided by a first set of components while the electrical apparatus is operating under a low power mode, and wherein the above-threshold load of the electrical apparatus is provided by a second set of components of the electrical apparatus while the electrical apparatus is operating under a high-power mode.

8. The electrical apparatus of claim 6, wherein the above-threshold load is intermittent over a duration of time during which the current from the alternating source is being drawn.

9. The electrical apparatus of claim 8, wherein the electrical apparatus is an additive printing apparatus, and wherein the above-threshold load is triggered when the electrical apparatus initiates performance of a print job.

10. The electrical apparatus of claim 8, wherein during the portion of the first time interval, the supply circuit supplies power to the first load independently of the power controller supplying power to the above-threshold load at the level that exceeds the predetermined level.

11. The electrical apparatus of claim 8, wherein the first load fluctuates during the first time interval, and wherein the supply circuit modulates the proportion and the remainder of the drawn current in response to the first load fluctuating.

12. The electrical apparatus of claim 8, wherein the above-threshold load fluctuates during the second time interval, and wherein the power controller controls an output of the battery to match the second fluctuating load.

13. The electrical apparatus of claim 8, wherein the power controller modulates the drawn current in supplying the charge current, so that the drawn current remains within a constant range, while the proportion of the drawn current powers a varying load of the electrical apparatus.

14. A method for controlling power to an electrical apparatus, the method comprising:
drawing current from an alternating current source at a level that is below a predetermined threshold;
using a proportion of the drawn current to continuously power an electrical apparatus at below the predetermined threshold, while supplying a charge current for the battery using a remainder of the drawn current; and
independently supplying power from the battery to the electrical apparatus at a level that exceeds the predetermined threshold during intervals in which a power requirement of the electrical apparatus exceeds the predetermined threshold.

15. The method of claim 14, further comprising supplying the charge current by modulating the drawn current, so that the drawn current remains within a constant range, while the proportion of the drawn current powers a varying load of the electrical apparatus.
